(19) United States
(12) Patent Application Publication
(10) Pub. No.: US 2006/0159146 A1
(43) Pub. Date: Jul. 20, 2006

(54) Semiconductor laser diode

(75) Inventors: Sho Iwayama, Aichi-ken (JP); Jun Minoura, Aichi-ken (JP); Tamiyo Umezaki, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Toyoda Gosei Co., Ltd., Nishikasugai-gun (JP)

(21) Appl. No.: 11/314,243

(22) Filed: Dec. 22, 2005

(30) Foreign Application Priority Data
Dec. 28, 2004 (JP) P2004-380369

(51) Int. Cl. H01S 5/00

(52) U.S. Cl. 372/49.01

(57) ABSTRACT

In a semiconductor laser diode, a mount portion is erected on a support member and a semiconductor laser diode chip is mounted on the mount portion. A window is formed on a cap, and a laser beam generated by the semiconductor laser diode chip is emitted through the window to an outside. An optical thin film layer and a photocatalyst layer are formed on an end face of a resonator at a light output side of the semiconductor laser diode chip.

This application is based on Japanese Patent Application No. 2004-380369, which is incorporated herein by reference.

### BACKGROUND OF THE INVENTION

1. Field of the Invention

The present invention relates to a semiconductor laser diode and more particularly to an improvement in an end face of a resonator of a semiconductor laser diode chip.

2. Description of the Related Art

Heretofore, a semiconductor laser diode has a structure in which a housing is filled with an inert gas, a semiconductor laser diode chip is mounted on a mount portion of a support member, and a cap for covering the semiconductor laser diode is fixed to the support member. A window is formed on the cap and a laser beam emitted from the semiconductor laser diode is emitted from this window to an outside (see JP-A-2000-164967). In the semiconductor laser diode, however, the housing is filled with the inert gas and a very small quantity of organic substance is present in the housing due to the contamination of the support member forming the housing, the cap or the semiconductor laser diode. It can be supposed that the organic substance is deposited on an end face of a resonator of the semiconductor laser diode and the end face of the resonator is thus damaged in some cases. Therefore, it has been proposed that a photocatalyst is applied to the cap of the housing, thereby decomposing the organic substance in the housing (see JP-A-2004-146496).

In the related semiconductor laser, however, the organic substance is decomposed and the photocatalyst applied to the housing does not perfectly decompose the organic substance in the early stage of driving. In some cases, therefore, a very small quantity of organic substance is stuck to the end face of the resonator of the semiconductor laser diode and a very small damage is thus generated on the end face, resulting in a deterioration in a reliability.

While TiO₂ which is a photocatalyst to be used usually exhibits a sufficient activity to ultraviolet rays, moreover, the sufficient activity cannot be obtained with a light emitting wavelength (for example, 405 nm) of a gallium nitride type compound semiconductor laser diode or in a semiconductor laser diode for emitting a normal visible light so that an organic substance cannot be decomposed sufficiently in some cases. In particular, the TiO₂ which is a photocatalyst to be used usually serves to apply a granular crystal. Therefore, it is hard to apply the crystal to the resonant end face of the semiconductor laser diode because an output thereof is influenced.

For this reason, a long time is required for controlling a process in order to eliminate the contamination of the support member, the cap and the semiconductor laser diode which form the housing as greatly as possible.

### SUMMARY OF THE INVENTION

The invention has been made in note of such a problem. It is an object of the invention to provide a structure of a semiconductor laser diode in which an organic substance is decomposed and is not stuck to an end face of a resonator of a semiconductor laser diode also in the early stage of a driving operation and the control of a process can be thus simplified.

Moreover, it is an object of the invention to enhance a reliability by using a photocatalyst to be fully activated at a light emitting wavelength of a semiconductor laser diode.

In order to achieve the object, a first aspect of the invention is directed to a semiconductor laser diode comprising a semiconductor laser diode chip, a housing of the semiconductor laser diode chip, a photocatalyst layer formed on a resonant end face of the semiconductor laser diode chip. Incidentally, the photocatalyst layer is formed on an end face of a resonator of the semiconductor laser diode chip.

According to the structure, the photocatalyst layer provided on the resonant end face is activated by a light so that an organic substance floating around the semiconductor laser diode can be decomposed and can be thus prevented from being stuck to the resonant end face. The light may be a light emitted from the semiconductor laser diode or a light irradiated from an outside.

A second aspect of the invention is directed to the semiconductor laser diode according to the first aspect of the invention, wherein the photocatalyst layer is activated by a light emitted from the semiconductor laser diode chip.

According to the structure, even if the organic substance is stuck onto the photocatalyst layer of the resonant end face of the semiconductor laser diode chip, the organic substance is decomposed by the light emitted from the semiconductor laser diode chip.

A third aspect of the invention is directed to the semiconductor laser diode according to the first aspect of the invention, wherein an optical thin film layer for controlling a reflectance is provided between the resonant end face and the photocatalyst layer.

According to the structure, the photocatalyst layer is formed on the optical thin film layer of the resonant end face. Therefore, it is possible to set the reflectance of the semiconductor laser diode in order to enhance an efficiency in the driving region of the semiconductor laser diode.

A fourth aspect of the invention is directed to the semiconductor laser diode according to the third aspect of the invention, wherein the optical thin film layer comprises Al₂O₃.

According to the structure, the optical thin film layer is formed of Al₂O₃. Therefore, it is possible to reduce the reflectance of the resonant end face, thereby enhancing an efficiency in the driving region of a high output semiconductor laser diode.

A fifth aspect of the invention is directed to the semiconductor laser diode according to any of the first to fourth aspects of the invention, wherein the photocatalyst layer comprises TiO_{2-X}N_{X}.

According to the structure, the photocatalyst layer comprises TiO_{2-X}N_{X}. Therefore, it is possible to efficiently activate the photocatalyst layer at the light emitting wavelength of the semiconductor laser diode.

According to the invention, an organic substance around the semiconductor laser diode is decomposed by a light emitted from the photocatalyst layer provided on the resonant end face and the semiconductor laser diode or a light irradiated from an outside also in the early stage of the driving operation of the semiconductor laser diode, and is prevented from being stuck to the resonant end face. Consequently, it is possible to simplify the control of a process without deteriorating the reliability of the semiconductor laser diode.

### BRIEF DESCRIPTION OF DRAWINGS

FIG. 1 is a typical view showing a structure of a semiconductor laser diode chip;

FIG. 2 is a view showing a layer structure provided on an end face of a resonator on a light output side of the semiconductor laser diode chip illustrated in FIG. 1;

FIG. 3 is a view showing a semiconductor laser diode according to an example of the invention;

FIG. 4 is a view showing another example of the semiconductor laser diode according to the invention; and

FIG. 5 is a view showing a semiconductor laser diode according to the related art.

### DETAILED DESCRIPTION OF THE PREFERRED EMBODIMENTS

Each element according to the invention will be described below in detail.

(Structure and Type of Semiconductor Layer of Semiconductor Laser Diode) A semiconductor laser diode generally has a layer structure in which a substrate, an n-type contact layer, an n-type clad layer, an n-type guide layer, an MQW layer, a p-type guide layer and a p-type contact layer are provided sequentially. A type of the semiconductor laser diode is not particularly restricted but can include a laser of a gain waveguide stripe type such as an electrode stripe type, a mesa stripe type or a hetero isolation type or a laser of a fixed waveguide stripe type such as a buried hetero type, a CSP type or a rib guide type.

In the case in which a semiconductor laser diode is formed by a group III nitride compound semiconductor, it is possible to generate a laser beam having a comparatively short wavelength. In case of the semiconductor laser diode, an optical energy is high, and furthermore, a chip itself is apt to have heat and an organic substance is easily stuck to an end face thereof.

The group III nitride compound semiconductor is expressed in a general formula of Al_{X}Ga_{Y}In_{1-X-Y}N (0≦X≦1, 0≦Y≦1, 0≦X+Y≦1) and includes a so-called binary system such as AlN, GaN and InN and a so-called ternary system such as Al_{X}Ga_{1-X}N, Al_{X}In_{1-X}N and Ga_{X}In_{1-X}N (0<X<1).

Boron (B) or thallium (Tl) may be substituted for at least a part of group III elements. Moreover, phosphorus (P), arsenic (As), antimony (Sb) or bismuth (Bi) may be substituted for at least a part of nitrogen (N).

The group III nitride compound semiconductor may contain an optional dopant. It is possible to use silicon (Si), germanium (Ge), selenium (Se), tellurium (Te) and carbon (C) for an n-type impurity. It is possible to use magnesium (Mg), zinc (Zn), beryllium (Be), calcium (Ca), strontium (Sr) and barium (Ba) for a p-type impurity. The group III nitride compound semiconductor can be heated by an electron beam irradiation, a plasma irradiation or a furnace after the p-type impurity is doped, which is not essential.

In the case in which a semiconductor laser diode is formed by a group III-V compound semiconductor using phosphorus (P) or As (arsenic) as a V group element, it is possible to generate a light having a comparatively long wavelength. The group III element can be selected optionally from Ga (gallium), In (indium) or Al (aluminum). More specifically, the III-V group compound semiconductor layer is expressed in a general formula of Al_{X}Ga_{Y}In_{1-X-Y}V (0≦X≦1, 0≦Y≦1, 0≦X+Y≦1, V: V group element), and includes a so-called binary type such as AlV, GaV and InV and a so-called ternary type such as Al_{X}Ga_{1-X}V, Al_{X}In_{1-X}V and Ga_{X}In_{1-X}V (0<X<1). Boron (B) or thallium (Tl) may be substituted for at least a part of the group III elements. In addition to As and P, moreover, nitrogen (N), antimony (Sb) or bismuth (Bi) can be substituted for at least a part of V.

The group III-V compound semiconductor layer may contain an optional dopant. It is possible to use silicon (Si), germanium (Ge), selenium (Se), tellurium (Te) and carbon (C) for an n-type impurity. It is possible to use magnesium (Mg), zinc (Zn), beryllium (Be), calcium (Ca), strontium (Sr) and barium (Ba) for a p-type impurity.

These semiconductor layers can be formed by a known film forming method. For example, it is possible to use a molecular beam epitaxial growth method (MBE method), a halide vapor phase epitaxial method (HVPE method), a puttering method, an ion plating method and a liquid phase growth method in addition to a metal organic chemical vapor deposition method (MOCVD method).

(Housing)

The semiconductor laser diode is disposed in an airtight housing. The housing according to the example is constituted by a support member having a mount portion and a cap, and the semiconductor laser diode is mounted on the mount portion and is further connected electrically to a lead.

The cap is provided with a window, and a laser beam emitted from the semiconductor laser diode is emitted through the window to an outside. The window is formed by a light transmitting material for transmitting at least a laser beam, for example, glass. The shape of the window can be selected optionally.

The shape of the housing can be selected optionally and a general purpose housing can be used exactly.

While the material of the housing is not particularly restricted, it is possible to use a metal material or a resin material such as an aluminum alloy or an iron alloy.

(Optical Thin Film Layer)

An optical thin film layer provided on a resonant end face at a side where a light of the semiconductor laser diode is output is set to have such a material and thickness as to reduce a reflectance of the resonant end face. For the material, it is possible to use Al₂O₃, SiO₂, etc. The thickness is determined by a refractive index of a semiconductor layer in the resonant end face and that of the optical thin film. The thickness is usually set to be 40 to 200 nm.

(Photocatalyst Layer)

It is sufficient that a photocatalyst layer can be activated by a light emitted from the semiconductor laser diode and can decompose an organic substance stuck to the resonant end face of a semiconductor laser diode chip. In other words, the photocatalyst layer is properly selected corresponding to a wavelength of a light emitted from the semiconductor laser diode. For example, rutile-type titanium oxide is preferable for a photocatalyst layer corresponding to a semiconductor laser diode formed by a group III nitride compound semiconductor for discharging a light having a short wavelength (for example, a light having a wavelength of 405 nm). TiO_{2-X}N_{X} obtained by doping TiO₂ with nitrogen is more preferable. Moreover, it is also possible to cause the photocatalyst layer to carry a noble metal as a promoter. Incidentally, a composition x is 0≦x<2.

A thickness of the photocatalyst layer is 10 to 150 nm, is preferably 50 to 120 nm, and is more preferably 70 to 100 nm. The thickness is determined by a necessary thickness for a recrystallization to function as the photocatalyst (which is more preferably greater) and an amount of absorption of the light of the semiconductor laser diode (which is more preferably smaller).

While the photocatalyst layer is formed on the end face of the resonator of the semiconductor laser diode in the example, it may be formed on the whole semiconductor laser diode, and furthermore, may be further formed in a portion on which a light emitted from the semiconductor laser diode is irradiated in the housing. For example, a photocatalyst may be formed on an inner peripheral surface of the housing, the support member or the mount portion. In this case, an internal surface of the cap can be a mirror plane in such a manner that the light can efficiently reach the photocatalyst in the same portion.

The example according to the invention will be described below.

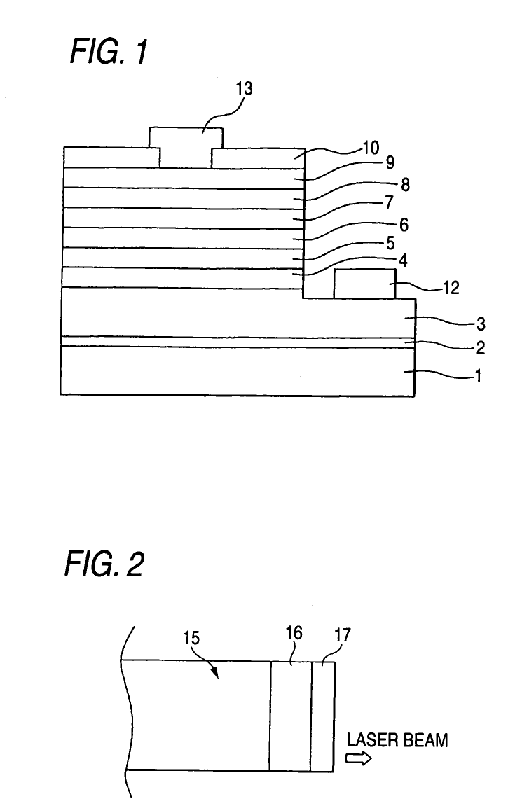

An example of the semiconductor laser diode chip is shown in FIG. 1.

A specification of each layer shown in FIG. 1 is as follows.

| Layer | Composition |
|---|---|
| Protective film 10 | SiO₂ |
| Third p-type layer 9 | GaN:Mg |
| Second p-type layer 8 | AlGaN:Mg |
| First p-type layer 7 | GaN:Mg |
| MQW layer 6 | InGaN/GaN |
| Third n-type layer 5 | GaN:Si |
| Second n-type layer 4 | AlGaN:Si |
| First n-type layer 3 | GaN:Si |
| Buffer layer 2 | AlN |
| Substrate 1 | Sapphire |

In the foregoing, the first n-type layer 3, the second n-type layer 4, the third n-type layer 5, the MQW layer 6, the first p-type layer 7, the second p-type layer 8 and the third p-type layer 9 function as an n-type contact layer, an n-type clad layer, an n-type guide layer, a light emitting layer, a p-type guide layer, an n-type clad layer and an n-type contact layer, respectively.

In the foregoing, GaN, InN, AlGaN, InGaN and AlInGaN can be used for a material of the buffer layer. Furthermore, the substrate and the buffer layer can also be removed after the formation of a semiconductor element if necessary.

GaN, AlGaN, InGaN or AlInGaN can be used for the n-type layers 3, 4 and 5.

While the n-type layers 3, 4 and 5 are doped with Si as the n-type impurity, moreover, it is also possible to use Ge, Se, Te and C as the n-type impurity.

For the MQW layer 6, it is possible to employ a multiquantum well structure of AlGaN/AlGaInN in addition to a multiquantum well structure of InGaN/GaN. It is preferable that the number of quantum well layers should be 5 to 30.

The p-type layers 7, 8 and 9 can also be formed by GaN, AlGaN, InGaN or InAlGaN. For a p-type impurity, moreover, it is also possible to use Zn, Be, Ca, Sr and Ba in place of Mg. It is also possible to reduce a resistance by a well-known method such as an electron beam irradiation, heating carried out by a furnace or a plasma irradiation after introducing the p-type impurity.

In a light emitting unit having the structure described above, a group III nitride compound semiconductor layer provided on the first n-type layer 3 can also be formed by an MBE method, an HVPE method, a sputtering method or an ion plating method in addition to an MOCVD method.

An n electrode 12 is formed by a material containing Al and is provided on the first n-type layer 3 exposed through an evaporation by forming the third p-type layer 9 and then removing a part of each of the semiconductor layers 4 to 9 and the first semiconductor layer 3 by etching.

A p-type electrode 13 is constituted by a material containing Ni and is formed by the evaporation.

FIG. 2 shows a layer structure provided on the resonant end face at the laser beam output side of the semiconductor laser diode chip.

An optical thin film layer 16 constituted by Al₂O₃ is formed in a thickness of 80 nm on the resonant end face and a photocatalyst layer 17 constituted by TiO_{2-X}N_{X} is formed in a thickness of 80 nm thereon sequentially by sputtering.

Then, a heat treatment (annealing) is carried out for approximately two hours at 550° C. in the nitrogen atmosphere to perform a crystallization in order to cause the photocatalyst layer to function as a photocatalyst. The TiO_{2-X}N_{X} is formed while the semiconductor laser diode chip is heated at a temperature of 400 to 900° C. Although the heat treatment to be carried out after the formation of the films can also be omitted, consequently, a performance is poorer as compared with the annealing to be performed after the formation of the films.

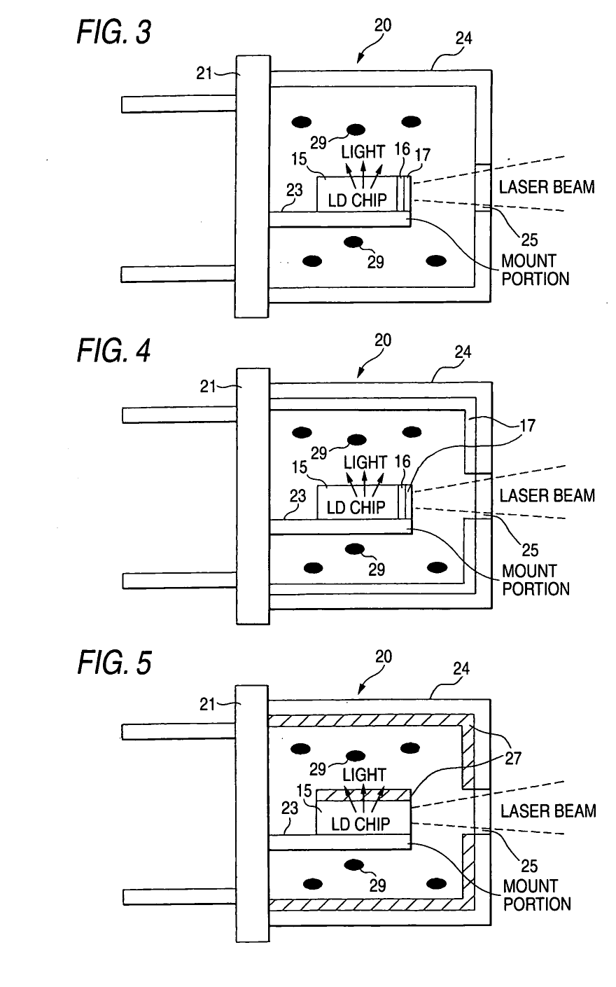

FIG. 3 shows a structure of a semiconductor laser diode 20 according to the example. In the semiconductor laser diode 20, a mount portion 23 is erected on a support member 21 and a semiconductor laser diode chip 15 (an LD chip in the drawing) is mounted on the mount portion 23. A cap 24 is provided with a window 25 and a laser beam generated by the semiconductor laser diode chip 15 is emitted through the window 25 to an outside.

The cap 24 is formed by a metallic thin plate. It is also possible to form the protective film 10 of the semiconductor laser diode chip by titanium oxide and to give a photocatalysis thereto.

According to the semiconductor laser diode 20 in accordance with the example which has such a structure, a laser beam emitted from the semiconductor laser diode chip 15 is emitted through the window 25 to an outside and functions as the semiconductor laser diode. Then, the photocatalyst layer 17 formed of TiO_{2-X}N_{X} is activated by a light emitted from the end face of the resonator on the light emitting output side of the semiconductor laser diode chip 15. Consequently, an organic substance 29 in the semiconductor laser diode 20 is oxidized and decomposed. Accordingly, the organic substance can be prevented from being stuck to the end face of the semiconductor laser diode chip. Consequently, it is possible to enhance the lifetime and reliability of the semiconductor laser diode chip, and furthermore, the semiconductor laser diode.

Additionally, it is possible to further form the photocatalyst layer 17 on an inner surface of the cap 24 as shown in FIG. 4.

In a related example shown in FIG. 5, a photocatalyst layer 27 is not present on an end face of a resonator on a light output side. For this reason, there is a possibility that an organic substance present around the end face of the resonator in a housing of a semiconductor laser diode might be stuck to an end face of a semiconductor laser diode chip (an LD chip in the drawing). In FIG. 5, the same elements as those in FIG. 5 have the same reference numerals and description thereof will be omitted.

The invention is not restricted to the description of the embodiment and example thereof. Various changes can also be included in the invention without departing from the description of the claims within a range that the skilled in the art can easily suggest.

What is claimed is:

1. A laser diode comprising:
a semiconductor laser diode chip;
a housing of the semiconductor laser diode chip; and
a photocatalyst layer formed on a resonant end face of the semiconductor laser diode chip.

2. The laser diode according to claim 1, wherein the photocatalyst layer is activated by a light emitted from the semiconductor laser diode chip.

3. The laser diode according to claim 1, wherein an optical thin film layer for controlling a reflectance is provided between the resonant end face and the photocatalyst layer.

4. The semiconductor laser diode according to claim 3, wherein the optical thin film layer comprises Al₂O₃.

5. The semiconductor laser diode according to claim 3, wherein the optical thin film layer comprises SiO₂.

6. The semiconductor laser diode according to claim 3, wherein a thickness of the optical thin film layer is 40 to 200 nm.

7. The laser diode according to claim 1, wherein the photocatalyst layer comprises rutile-type titanium oxide.

8. The laser diode according to claim 1, wherein the photocatalyst layer comprises TiO_{2-X}N_{X}.

9. The laser diode according to claim 1, wherein a thickness of the photocatalyst layer is 10 to 150 nm.

10. The laser diode according to claim 1, wherein a thickness of the photocatalyst layer is 50 to 120 nm.

11. The laser diode according to claim 1, wherein the photocatalyst layer is formed on an inner surface of the housing.

12. The laser diode according to claim 1, wherein the photocatalyst layer is formed on an end face of a resonator of the semiconductor laser diode chip.

13. The laser diode according to claim 1, wherein the semiconductor laser chip comprises a layer structure comprising a substrate, an n-type contact layer, an n-type clad layer, an n-type guide layer, an MQW layer, a p-type guide layer and a p-type contact layer sequentially.

14. The laser diode according to claim 1, wherein the semiconductor laser chip comprises a group III nitride compound semiconductor.

15. The laser diode according to claim 1, wherein the housing comprises a mount portion, and wherein the semiconductor laser diode chip and the photocatalyst layer are mounted on the mount portion.
